(19) United States
(12) Patent Application Publication
(10) Pub. No.: US 2024/0395966 A1
(43) Pub. Date: Nov. 28, 2024

(54) LIGHT-EMITTERS WITH GROUP III-NITRIDE-BASED QUANTUM WELL ACTIVE REGIONS HAVING GAN INTERLAYERS

(71) Applicant: Wisconsin Alumni Research Foundation, Madison, WI (US)

(72) Inventors: Guangying Wang, Madison, WI (US); Shubhra Pasayat, Middleton, WI (US); Chirag Gupta, Middleton, WI (US)

(21) Appl. No.: 18/322,861

(22) Filed: May 24, 2023

(51) Int. Cl. H01L 33/02; H01L 33/00; H01L 33/06; H01L 33/32; H01S 5/343

(52) U.S. Cl. CPC H01L 33/025; H01L 33/007; H01L 33/06; H01L 33/32; H01S 5/34333; H01S 5/34346; H01S 5/20

(57) ABSTRACT

Group III-nitride-based light-emitting devices are provided. The light-emitting devices are characterized by an active region having one or more quantum wells. The one or more quantum wells having a double well design provided by a first well layer comprising an AlInGaN alloy or an InGaN alloy and an adjacent GaN interlayer, both of which are disposed between two barrier layers comprising an AlGaN alloy or a low-In-content AlInGaN alloy.

### BACKGROUND

Ultraviolet (UV) Light-emitting Diodes (LEDs) are widely used in medical, scientific, and military applications. When compared with conventional UV light-emitting sources, UV LEDs are compact, efficient, and environmentally friendly. LEDs with chip dimensions below 100 μm are commonly referred to as micro-LEDs (μLEDs). μLEDs have additional advantages in sustaining and delivering higher current density. Additionally, smaller device sizes result in higher light extraction efficiency, higher output power, and smaller redshift in comparison to large devices. Therefore, UV μLEDs are expected to have an improved device performance compared to regular sized LEDs (>100 μm). Group III-Nitride materials are commonly used in the development of UV-A to UV-C LEDs, which span the wavelength ranges of 200 nm-400 nm. In the UV-A range LEDs which cover wavelengths from 365 nm to 405 nm, InGaN/AlGaN structure designs are commonly used in the active region. These structures are primarily grown by metalorganic vapor-phase epitaxy (MOCVD).

### SUMMARY

Group III-nitride-based light-emitting devices, such as light-emitting diodes and laser diodes, are provided. Methods of making the light-emitting devices are also provided.

One embodiment of a light-emitting device includes: (a) an active region comprising one or more quantum wells, wherein the one or more quantum wells are formed by one or more repeating periods of a heterostructure comprising: (i) a well layer comprising In_{z}Ga_{1-z}N, where 0<z≤0.3, or AlᵢInⱼGa₁₋ᵢ₋ⱼN, where 0<i≤1 and 0<j≤1; (ii) an interlayer comprising GaN; and (iii) a barrier layer comprising Al_{y}Ga_{1-y}N, where 0<y≤1, or AlₖInₗGa₁₋ₖ₋ₗN, where 0<k≤1 and 0<l≤1; (b) a first electrically conductive contact in electrical communication with a first side of the active region; (c) a second electrically conductive contact in electrical communication with a second, opposing side of the active region; and (d) a voltage source connected to the first and second electrically conductive contacts. In the light-emitting devices, the first electrically conductive contact, the second electrically conductive contact, and the voltage source are configured to apply an electric field across the active region.

One embodiment of a method of growing a periodic group III-nitride heterostructure includes the steps of: growing a first period of the group III-nitride heterostructure using the steps of: (a) depositing a well layer comprising In_{z}Ga_{1-z}N, where 0<z≤0.3, or AlᵢInⱼGa₁₋ᵢ₋ⱼN, where 0<i≤1 and 0<j≤1, on a substrate, wherein the well layer is deposited via metal organic chemical vapor deposition from two or more metal organic precursor molecules and one or more nitrogen-containing precursor molecules in a carrier gas composition comprising N₂; (b) depositing an interlayer comprising GaN on the well layer, wherein the interlayer is deposited via metal organic chemical vapor deposition from two or more metal organic precursor molecules and one or more nitrogen-containing precursor molecules in a carrier gas composition comprising H₂, N₂, or a mixture of H₂ and N₂; (c) depositing a barrier layer comprising Al_{y}Ga_{1-y}N, where 0<y≤1, or AlₖInₗGa₁₋ₖ₋ₗN, where 0<k≤1 and 0<l≤1, on the interlayer, wherein the barrier layer is deposited via metal organic chemical vapor deposition from two or more metal organic precursor molecules and one or more nitrogen-containing precursor molecules in a carrier gas comprising H₂, N₂, or a mixture of H₂ and N₂; (d) varying the carrier gas composition, a growth temperature, or both during the deposition of the well layer, the interlayer, or both. Steps (a)-(d) can be repeated one or more times to grow one or more additional periods of the group III-nitride heterostructure, wherein the substrate in step (a) for each of the one or more additional layers is the barrier layer of a previous period of the group III-nitride heterostructure.

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

FIG. 1 is a cross-sectional view of one period in a multiple quantum well (MQW) active region.

FIG. 2A is a schematic diagram showing a cross-sectional view of an LED. FIG. 2B is a schematic diagram showing a cross-sectional view of a laser diode (LD).

FIG. 3 shows energy band diagrams for a quantum well with a GaN interlayer in an MQW active region and for a comparable quantum well without a GaN interlayer in an MQW active region.

FIGS. 4A-4B show simulation structures with (FIG. 4A) a conventional InGaN/AlGaN active region design and with (FIG. 4B) an InGaN/GaN/AlGaN active region design. FIG. 4C shows a band diagram simulation comparison for the devices of FIGS. 4A and 4B. FIG. 4D shows an IQE simulation comparison for the devices of FIGS. 4A and 4B.

FIGS. 5A-5D show electro-luminescence spectra with current densities ranging from 10 to 100 A/cm² for a 100×100 μm² LED with an acquisition time of 3 s (FIG. 5A), for a 60×60 μm² LED with an acquisition time of 5 s (FIG. 5B), for a 40×40 μm² LED with an acquisition time of 5 s (FIG. 5C), and for a 20×20 μm² LED with an acquisition time of 5 s (FIG. 5D) (except 100 A/cm² was acquired at 1 s).

FIG. 6A shows the voltage vs. current density for the 20×20 μm² to 100×100 μm² devices. FIG. 6B shows the relative EQE vs. current density for the 20×20 μm² to 100×100 μm² devices in comparison to the 100×100 μm² device.

### DETAILED DESCRIPTION

Group III-nitride-based light-emitting devices, such as LEDs and LDs, are provided. The light-emitting devices are characterized by an active region having a QW structure. The quantum wells in the QW structure have a double well design provided by a first well layer comprising an AlInGaN alloy or an InGaN alloy and an adjacent GaN interlayer, both of which are disposed between two barrier layers comprising an AlGaN alloy or a low-In-content AlInGaN alloy. The inclusion of the GaN interlayer in the quantum well structure enhances electron and hole wave function overlap in the quantum well energy band structure and improves the crystal quality of an AlGaN barrier layer that is grown epitaxially on the GaN, relative to a barrier layer grown epitaxially on the AlInGaN or InGaN alloys. The result is an active region with increased carrier recombination efficiency and a light-emitting device with improved internal quantum efficiency (IQE). The AlInGaN and InGaN alloys used in the well layers of the MQW structure are referred to collectively herein as (Al)InGaN alloys; the AlGaN and low-In-content AlInGaN alloys used in the barriers are referred to collectively herein as Al(In)GaN alloys. In embodiments of the active region in which the well layers and barrier layers both comprise an AlInGaN alloy, the AlInGaN alloys of the well layers and the barrier layers have different AlInGaN compositions.

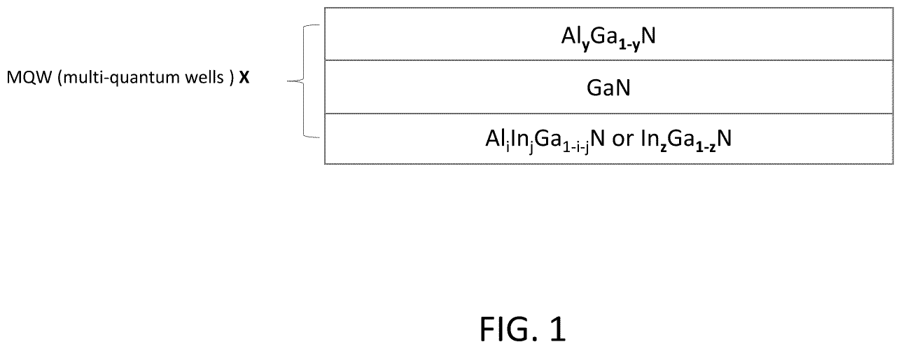

FIG. 1 is a schematic diagram showing a cross-sectional view of a portion of an active region that includes an (Al)InGaN well layer 102, a GaN interlayer 104, and an Al(In)GaN barrier layer. Multiple periods of this trilayered heterostructure are stacked to provide an active region having an MQW structure.

### Light-Emitting Devices.

In the light-emitting devices, carriers (electrons and holes) are injected into the MQW-structured active region under the influence of an electric field applied across the device heterostructure. In the active region, the carriers recombine to emit photons. In addition to the MQW active region, the devices include two or more electrically conductive contacts positioned to apply the electric field across the heterostructure, including across the MQW active region, and a voltage source coupled to the electrically conductive contacts to apply a voltage difference between the contacts, thereby generating the electric field. Light-emitting devices that emit over different wavelength ranges, including the ultraviolet to near infrared regions of the electromagnetic spectrum, can be fabricated. LEDs, including μLEDs having chip dimensions below 100 μm, and LDs are two types of devices into which the active regions can be incorporated. Electrically conductive contacts that are positioned to apply an electric field across the active region when the light-emitting device is in operation are referred to as being in electrical communication with the heterostructure active region. However, the electrically conductive contacts need not be in direct physical contact with the active region; they may be separated from the active region by one or more additional device layers.

### LEDs.

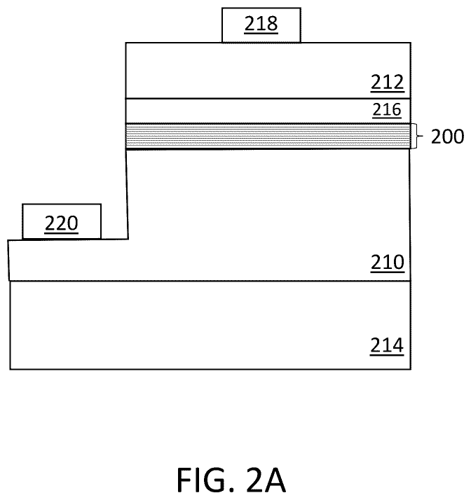

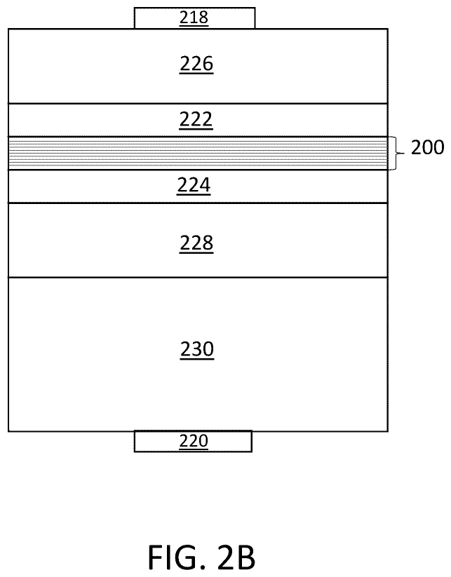

FIG. 2A is a schematic diagram showing an MQW-structured active region 200 integrated into an LED. In the LED, the active region is disposed between an electron-injection layer 210 comprising an n-type semiconductor and a hole-injection layer 212 comprising a p-type doped semiconductor. The LED heterostructure is grown on a substrate 214. Optionally, an electron blocking layer (EBL) 216 comprising a semiconductor having a higher bandgap than the p-type doped semiconductor may be disposed between the p-type doped semiconductor and the active region to avoid leakage of electrons into the p-type doped semiconductor. Electron injection layer 210, hole-injection layer 212, and EBL 216 may be made from, for example, group III-nitride semiconductors.

During operation of the LED, a forward bias is applied to the heterostructure through an electrically conducting (typically metallic) p-contact 218 on hole injection layer 212 and an electrically conducting (typically metallic) n-contact 220 on electron injection layer 210. This applied bias causes electrons from the electron injection layer and holes from the hole injection layer to flow to the active region, where they are captured by quantum wells and recombine to generate light. Suitable p-type doped semiconductors for the hole injection layer include Mg-doped GaN; suitable n-type doped semiconductors for the electron injection layer include Si-doped GaN; and suitable materials for the EBL include AlGaN alloys. Sapphire is an example of a substrate upon which the LED heterostructure can be grown.

### LDs.

FIG. 2B is a schematic diagram showing an MQW-structured active region 200 integrated into an LD. In the LD, the active region is disposed between a first waveguide layer 222 comprising a p-type doped or undoped group III-nitride semiconductor, such as AlGaN, AlInGaN, or GaN, a second waveguide layer 224 disposed opposite first waveguide layer 222 and comprising an undoped or n-type doped group III-nitride semiconductor, such as AlGaN, AlInGaN, or GaN, a first cladding layer 226 comprising a p-type doped group III-nitride semiconductor, such a p-AlGaN, over first waveguiding layer 222, and a second cladding layer 228 comprising an n-type doped group III-nitride semiconductor, such as n-AlGaN, on second waveguide layer 224, opposite first cladding layer 226. Optionally, an EBL comprising a p-type doped group III-nitride semiconductor, such as AlGaN, can be inserted between first waveguide layer 222 and first cladding layer 226 or between the MQW active region 200 and first waveguide layer 222. The waveguide layers are characterized in that they are more lightly-doped than their respective cladding layers. The LD heterostructure is supported by a substrate 230.

The light-emitting devices may also include additional layers that are standard in such devices, including buffer layers and/or nucleation layers that are used to facilitate the growth of high-quality crystalline layers epitaxially on a lattice mismatched substrate.

### Active Region Materials

The active regions of the light-emitting devices have at least one period of the (Al)InGaN/GaN/Al(In)GaN heterostructure to provide at least one quantum well. Some embodiments of the active regions have at least two periods of the (Al)InGaN/GaN/Al(In)GaN heterostructure to provide at least two quantum wells. More typically, the active regions will have between 3 and 10 periods (for example, 7 to 8 periods), although a higher number of periods can be used.

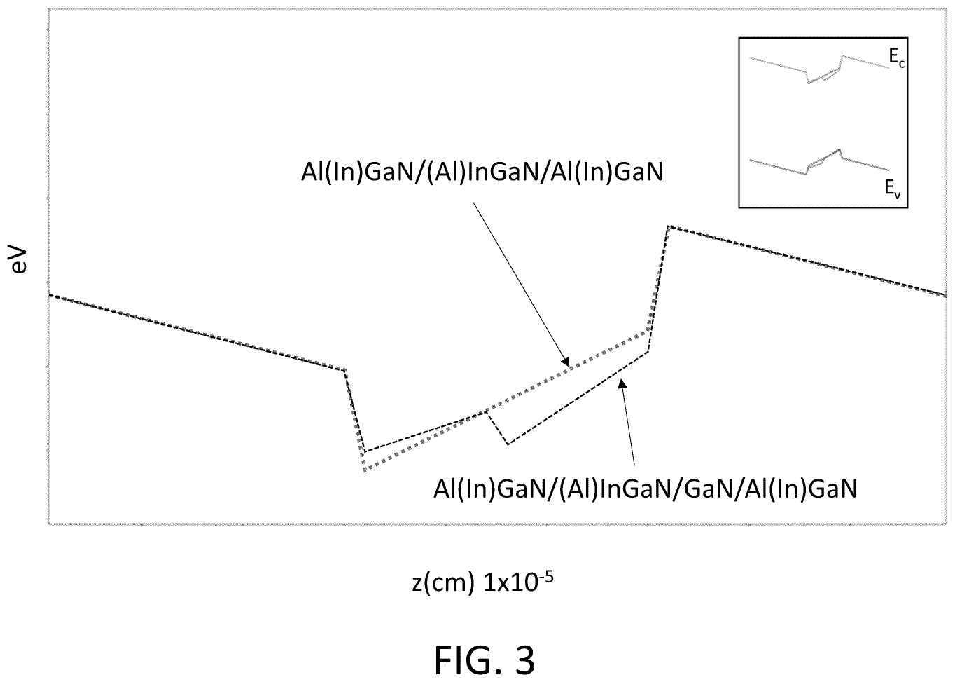

Because the (Al)InGaN well layer and GaN interlayer have lower bandgaps than the Al(In)GaN barrier layers, carriers (electrons and holes) are confined in the low bandgap regions of the MQW structure. Due to the spontaneous and piezoelectric polarization of the group-III nitrides, which give rise to the quantum confined Stark effect (QCSE), the energy band profile of the quantum wells adopts a saw-tooth shape that reduces the electron and hole wavefunction overlap in the quantum well, thereby decreasing the probability for radiative carrier recombination. FIG. 3 shows a generic conduction energy band diagram for a quantum well composed of a single (Al)InGaN well layer sandwiched between two Al(In)GaN barrier layers having a single well profile (dotted line). For comparison, a conduction energy band diagram for a quantum well composed of a first (Al)InGaN well layer and an intervening GaN layer sandwiched between two Al(In)GaN barrier layers is also shown (dashed line). As seen in the diagram, the insertion of the intervening GaN layer provides a double well structure in the conduction band. For simplicity, the valance band is omitted from enlarged portion of the band diagram in FIG. 3. However, the double well structure is also naturally present in the valance energy band, as illustrated in the inset in the upper right of FIG. 3. Relative to the single well energy band profile, the double well energy band profile results in an enhanced electron and hole wave function overlap and an increased carrier recombination efficiency. In the double well structure, the bandgaps of the well layer and the interlayer are desirably very similar. For example, the active regions can be designed such that the bandgap of the well layer and the bandgap of the interlayer differ by no more than 5%.

In the MQW structures, the (Al)InGaN and GaN layers are thin layers disposed between thicker layers of the higher bandgap Al(In)GaN barriers. Typical layer thicknesses for the (Al)InGaN well layer include thicknesses of less than 15 nm and typical thicknesses for the GaN layer include thicknesses of less than 15 nm. The (Al)InGaN alloy may be In_{z}Ga_{1-z}N, where 0<z≤0.3 or AlᵢInⱼGa₁₋ᵢ₋ⱼN, where 0<i≤1 and 0)<j≤1. The values of z, i, and j will depend on the operating wavelengths of the light-emitting device, whereby a higher indium content will generally provide a device with a longer operating wavelength.

In addition to producing a double well structure and improving carrier recombination, the GaN interlayers in the MQW action region allows the Al(In)GaN barriers to be grown with higher crystal quality, resulting in a higher IQE, as discussed in more detail below and illustrated in the Example.

The Al(In)GaN barrier layers in the MQW active region are Al_{y}Ga_{1-y}N alloys, where 0<y≤1, or AlₖInₗGa₁₋ₖ₋ₗN, where 0<k≤1 and 0<l≤1. The barrier layers are thicker than the well layers but should be sufficiently thin to allow the carrier to overcome the barrier. Therefore, the barrier layers typically have a thickness of 25 nm or less and more commonly have a thickness in the range from about 10 nm to about 15 nm. Optionally, the Al(In)GaN barrier layers can have a graded or stepped (stratified) Al(In)GaN alloy composition, in which the Al content increases or decreases between the GaN interlayer/Al(In)GaN barrier interface and the Al(In)GaN barrier/(Al)InGaN well interface, or increases between the GaN interlayer/Al(In)GaN barrier interface and the Al(In)GaN barrier/(Al)InGaN well interface. In some embodiments, the Al(In)GaN barrier layers are both graded and stepped-having graded compositions of different Al(In)GaN alloys in each of two or more different strata of a stepped barrier.

Optionally, the (Al)InGaN, GaN, and Al(In)GaN alloys may be doped to optimize band alignment and reduce the QCSE. The dopants may be n-type, such as silicon (Si), or p-type, such as magnesium (Mg) or carbon (C), dopants.

### Device Fabrication.

The group III-nitride layers in the device heterostructure, including the active region, can be grown using vapor deposition methods, such as MOCVD, plasma chemical vapor deposition (CVD), or hot-filament CVD, or by molecular beam epitaxy (MBE). The metal contacts can be deposited by metal deposition techniques, such as atomic layer deposition (ALD), sputtering, or evaporation. Various metals, metal alloys, and electrically conducting oxides can be used to form electrically conducting contacts. By way of illustration only, contacts can be composed of gold, platinum, chromium, tungsten, titanium, aluminum, nickel, gold, or alloys thereof.

The growth of the heterostructure takes place in a vacuum chamber in which a growth substrate typically is supported on a rotatable platform. A heat source (e.g., a resistive heater) in thermal communication with the growing heterostructure can be used to tailor the growth temperature for each of the various material layers to provide high-quality crystal growth. Typical growth temperatures include temperatures in the range from about 400° C. to about 1500° C. and, more commonly, in the range from about 1000° C. to about 1300° C.; however, suitable growth temperatures will depend on the material being grown.

Epitaxial growth using vapor deposition is carried out by exposing the substrate or the previously grown layer of the heterostructure to metal-containing and nitrogen-containing precursor molecules that decompose and react to form the various layers. These precursors may be introduced into the vacuum chamber with a carrier gas, such as hydrogen (H₂) or nitrogen (N₂). For MOCVD growth, the precursors are metal organic compounds, such as trimethyl gallium (TMGa), triethyl gallium (TEGa), trimethyl aluminum (TMAl), triethyl aluminum (TEAl), trimethyl indium (TMI), and triethyl indium (TEI). Ammonia (NH₃) is typically used as a nitrogen precursor molecule. For the growth of doped semiconductors, a dopant-containing precursor (e.g., silane (SiH₄) for Si doping or magnesocene (bis (cyclopentadienyl) magnesium (Cp₂Mg)) for Mg doping) is also introduced into the chamber.

By adjusting the carrier gases, growth temperature, or both during the growth of a material layer, high quality crystal layers with precisely tailored material properties can be grown. Moreover, by adjusting the carrier gas composition and/or growth temperature during the growth of the heterostructure continuous (uninterrupted) growth of a high-quality heterostructure can be achieved. The use of the GaN interlayer in the active region provides an enhanced flexibility in selecting and tuning carrier gases and growth temperature.

The choice of carrier gas and temperature for the MOCVD growth of the active region strongly influences the morphology and crystal quality of the layers in the heterostructure and the IQE of the light-emitting device into which it is incorporated. The presence of indium in the (Al)InGaN well layers of the active region results in an improved light emission due to its band-filling effect, which contributes to a higher IQE. For effective indium incorporation, the growth of (Al)InGaN favors a lower growth temperature and nitrogen (N₂) as a carrier gas. This is because the use of H₂ as a carrier gas and a high growth temperature lower the indium content in the InGaN film via In desorption and roughen the surface. In contrast, the Al(In)GaN barrier layers favor growth in a hydrogen carrier gas and high growth temperatures to obtain a good crystal quality. However, the use of disparate growth conditions for the (Al)InGaN well layers and the Al(In)GaN barrier layer in a (Al)InGaN/Al(In)GaN-based MQW structure (i.e., an MQW structure lacking GaN intervening layers) is challenging. If the Al(In)GaN barrier layer is grown using N₂ as the carrier gas, the crystal quality may be compromised by defect formation, including the formation of defects that propagate from the (Al)InGaN well layer into the Al(In)GaN barrier layer. However, if the Al(In)GaN barriers are grown in H₂, the indium concentration in the previously grown (Al)InGaN well layer will be reduced by the exposure to H₂ during the initial growth of the Al(In)GaN when the (Al)InGaN/Al(In)GaN interface is formed. Moreover, exposing the (Al)InGaN to a higher temperature at the onset of Al(In)GaN growth can cause thermal degradation of the (Al)InGaN layer and the formation of v-pits in the crystal, thereby degrading the optical performance of the device into which the active region is incorporated by increasing the non-radiative recombination.

The use of a GaN interlayer in the MQW structure addresses these challenges and provides greater design flexibility for MOCVD growth. The (Al)InGaN well layer is desirably grown using N₂ as the carrier gas. In some embodiments of the MOCVD growth process, the carrier gas composition used during the subsequent growth of the GaN interlayer changes during GaN growth to preserve the crystal quality of the underlying (Al)InGaN, while providing a favorable environment for the Al(In)GaN barrier layer that is subsequently grown on the GaN. For example, during the initial stage of GaN growth, N₂ can be used as the carrier gas until the GaN layer reaches a given thickness. During this growth stage, the underlying (Al)InGaN is not exposed to H₂. Then, during the next stage of GaN growth, the carrier gas composition can be altered by introducing H₂ to form an N₂ and H₂ carrier gas mixture, or by replacing the N₂ carrier gas with H₂. The use of H₂ as a carrier gas during GaN growth is advantageous because H₂ generally provides a better GaN crystal quality than does N₂. The composition of the N₂/H₂ gas mixture may remain constant until the GaN reaches its final thickness, or the H₂ content of the carrier gas mixture can be increased over time, such that the H₂ concentration is initially low, but increases as the GaN is grown, until the carrier gas mixture is entirely or mostly (>50 mol. %, >70 mol. %, or <90 mol. %) H₂ by the time the GaN layer reaches it full thickness. The introduction of the H₂ may be continuous and gradual to provide a steady (for example, linear) increase in the H₂ concentration or may occur at one or more discrete time intervals to provide a stepped increase in the H₂ concentration. In the constant-composition or changing-composition N₂/H₂ gas mixtures, the mole ratio of N₂ to H₂ can be represented by AN₂/(1−A)H₂, where 0<A<1.

In some embodiments of the MOCVD growth methods, including those in which the carrier gas composition changes during the growth of the GaN interlayer, the carrier gas composition used during the growth of the Al(In)GaN barrier layers is H₂, N₂, or a mixture thereof. In some of these embodiments, the carrier gas composition changes during Al(In)GaN growth to produce a high-quality crystal. The composition of the N₂/H₂ gas mixture may remain constant until the Al(In)GaN reaches its final thickness, or the H₂ concentration in the N₂ carrier gas mixture may be increased over time, such that the H₂ concentration is initially low, but increases as the Al(In)GaN is grown, until the carrier gas mixture is entirely or mostly (>50 mol. %, >70 mol. %, or <90 mol. %) H₂ by the time the Al(In)GaN layer reaches it full thickness. The introduction of the H₂ may be continuous and gradual to provide a steady (for example, linear) increase in the H₂ concentration or may occur at one or more discrete time intervals to provide a stepped increase in the H₂ concentration. In the constant-composition or changing-composition N₂/H₂ gas mixtures, the mole ratio of N₂ to H₂ can be represented by AN₂/(1−A)H₂, where 0<A<1. The carrier gas composition for the Al(In)GaN barrier may be selected based on the Al(In)GaN composition; if the barrier is AlGaN (i.e., free of In), an H₂ carrier gas or an N₂/H₂ gas mixture with a high H₂ content may be favored, while a lower N₂ content may be preferable for a low-In-content AlInGaN barrier in order to reduce In desorption.

The adjustments to the carrier gas composition during MOCVD growth may be conducted without interrupting (i.e., stopping and restarting) the ongoing heterostructure deposition process, such that continuous, uninterrupted growth is achieved. However, the present MOCVD growth methods do allow for interrupted growth.

During MOCVD growth, the growth temperature can be tailored independently for each layer as it is grown. However, it is also possible to change the growth temperature during the growth of any given layer in order to achieve a high-quality heterostructure. These temperature adjustments can be conducted in addition to, or as an alternative to, the carrier gas adjustments discussed above. By way of illustration, suitable temperatures for the MOCVD growth of an InGaN well layer include those in the range from 300 to 1200° C.; suitable growth temperatures for the MOCVD growth of an AlInGaN well layer include those in the range from 300 to 1400° C.; suitable temperatures for the MOCVD growth of a GaN layer include those in the range from 300 to 1300° C.; suitable temperatures for the MOCVD growth of an AlGaN barrier layer include those in the range from 300 to 1300° C.; and suitable temperatures for the MOCVD growth of a low-In-content AlInGaN barrier layer include those in the range from 300 to 1400° C. However, temperatures outside of these ranges can be used.

Because In tends to desorb at higher temperatures, the (Al)InGaN well layers are desirably grown at lower temperatures than the Al(In)GaN barrier layers and GaN layers. Moreover, it is advantageous to avoid exposing the (Al)InGaN layer to a high temperature at the onset of the growth of the overlying GaN layer. In addition, it may be advantageous to grow a low-In-content AlInGaN barrier layer at a lower temperature than an AlGaN barrier layer.

In some embodiments of the MOCVD methods of growing the active regions, the growth temperature is changed-increased or decreased-during the growth of the GaN interlayers, the Al(In)GaN barrier layers, or both. For example, the growth temperature may be increased during the growth of the GaN interlayers. In some embodiments, the growth temperature at the onset of GaN deposition is at or near the growth temperature used to deposit the underlying (Al)InGaN well layer in order to limit or minimize desorption of In from the exposed underlying (Al)InGaN. Then, during the next stage of GaN growth, the temperature is increased to improve the quality of the GaN. The GaN growth temperature may be ramped up to a desired temperature, which is maintained until the GaN reaches its final thickness, or the temperature may be increased over time, such that the growth temperature is at or near the desired temperature for Al(In)GaN growth when the GaN layer reaches it full thickness. The temperature increase may be continuous and gradual to provide a steady (for example, linear) increase in temperature, or may occur continually in stages to provide a stepped temperature profile during GaN growth.

In some embodiments of the MOCVD growth methods, including those in which the temperature changes during GaN interlayer growth, the growth temperature is changed-increased or decreased-during the growth of the Al(In)GaN barrier layers. In some embodiments, the growth temperature at the onset of Al(In)GaN deposition is at or near the growth temperature used to deposit the underlying GaN interlayer. Then, during the next stage of Al(In)GaN growth, the temperature is increased to improve the quality of the Al(In)GaN. The Al(In)GaN growth temperature may be ramped up to a desired temperature, which is maintained until the Al(In)GaN reaches its final thickness, or the temperature may be increased over time. The temperature increase may be continuous and gradual to provide a steady (for example, linear) increase in temperature, or may occur continually in stages to provide a stepped temperature profile during Al(In)GaN growth.

The adjustments to the growth temperature during MOCVD growth may be conducted without interrupting (i.e., stopping and restarting) the ongoing heterostructure deposition process, such that continuous, uninterrupted growth is achieved. However, the present MOCVD growth methods do allow for interrupted growth.

If Al(In)GaN barrier layers having a graded or stepped compositional profile are desired, the ratio of precursors in the vapor can be adjusted during the growth of the barrier. The ratio of the precursors can be changed continuously and gradually to provide a steady (for example, linear) change in the Al(In)GaN alloy composition, or may occur at one or more discrete time intervals to provide an Al(In)GaN barrier with a stepped compositional profile. Adjustments in the ratio of the precursors may be carried out along with the carrier gas adjustments and/or the growth temperature adjustments discussed above.

### EXAMPLE

This example illustrates the growth and characterization of an ultraviolet light-emitting diode having an InGaN/GaN/AlGaN MQW-structured active region.

Micro-LED structures were fabricated with mesa sizes ranging from 20×20 μm² to 100×100 μm² with an emission wavelength of 372 nm.

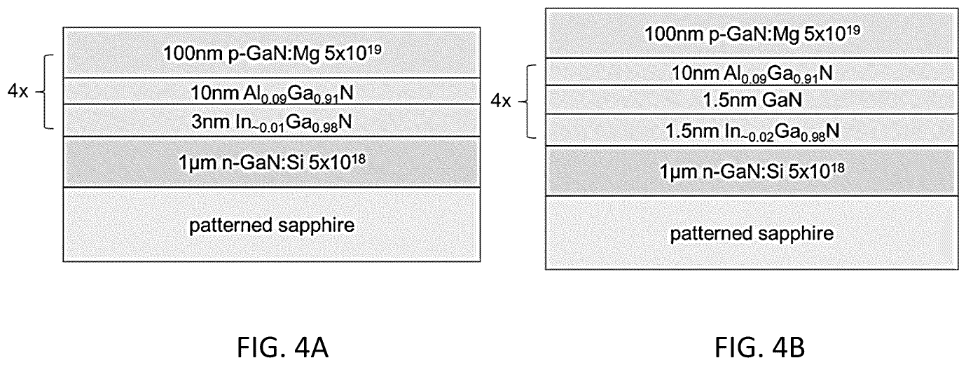

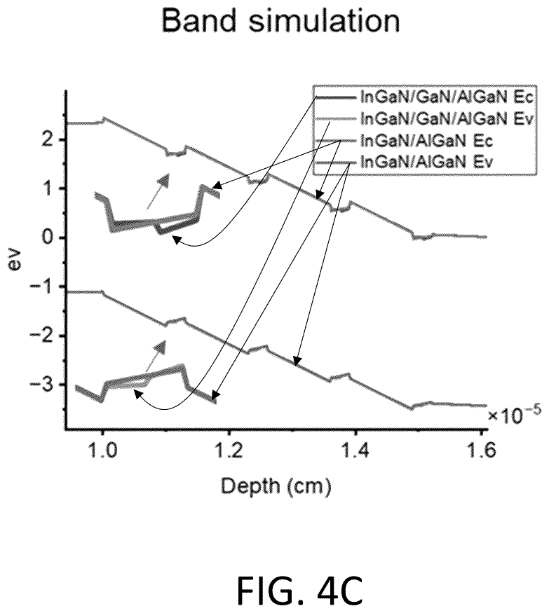

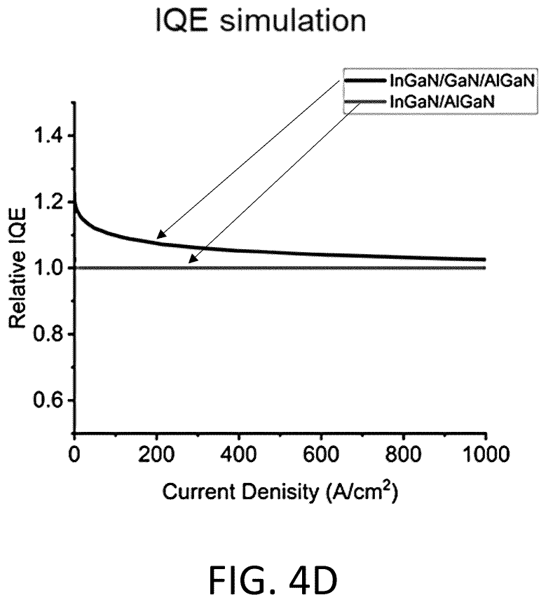

The software used in this simulation is One-Dimensional Poisson, Drift-Diffusion, and Schrodinger Solver (1D-DDCC) from Optoelectronic Device Simulation Laboratory. (Optoelectronic Device Simulation Laboratory http://yrwu-wk.ee.ntu.edu.tw.) Two LED structures were simulated for comparison: InGaN/AlGaN (FIG. 4A) and InGaN/GaN/AlGaN (FIG. 4B). In the InGaN/AlGaN structure, the layers included a 1-μm-thick Si-doped n-GaN layer (n-doping=5×10¹⁸ cm⁻³), 4 pairs of In_{˜0.01}Ga_{0.98}N (3 nm)/Al_{0.09}Ga_{0.91}N (10 nm) MQWs, and a 100 nm thick p-GaN layer with Mg doping (p-doping=5×10¹⁹ cm⁻³). In the InGaN/GaN/AlGaN structure, MQWs were modified to 4 pairs of In_{˜0.02}Ga_{0.98}N (1.5 nm)/GaN (1.5 nm)/Al_{0.09}Ga_{0.91}N (10 nm). The thickness and composition of the InGaN layer were modified to have a similar indium concentration as the InGaN/AlGaN structure. This ensured the effect of indium concentration and the polarization charge in the two structures remained nominally the same, which granted a fair comparison between the two structures. The goal of this study was to compare the novel InGaN/GaN/AlGaN structure with the conventional InGaN/AlGaN structure; therefore, GaN was chosen for p and n doped layers for simplicity.

The bandgap simulation is presented in FIG. 4C, where the electron band (E_{c}) and valence band (Eᵥ) of the InGaN/AlGaN structure, and the E_{c} and Eᵥ of the InGaN/GaN/AlGaN structure are labeled. This band diagram shows that the GaN interlayer in the InGaN/GaN/AlGaN behaved like a second well in the structure, which will result in an enhanced electron and hole wave function overlap in comparison with the InGaN/AlGaN structure, which increased the recombination efficiency. Moreover, the InGaN/GaN/AlGaN structure showed improvement in the IQE simulation, with more than 10% improvement in the operating current density range from 0 to 100 A/cm² (FIG. 4D). The IQE advantage decreased with higher current density (>200 A/cm²) possibly due to the recombination being dominated by Auger recombination. In general, LEDs are operated at less than 100 A/cm², especially μLEDs. This IQE simulation showed that this novel InGaN/GaN/AlGaN structure not only improves the crystal quality from a growth perspective but also provides an advantage in IQE from the fundamental structure design. This design was validated through experiments.

LED structures were grown using MOCVD on standard c-plane 4 μm thick GaN on patterned sapphire substrates (PSS). The structure was the same as the simulated structure FIG. 4B with the addition of a 20 nm heavily doped p⁺-GaN layer (p-doping=5×10²⁰ cm⁻³). The Mg dopants in the p-layers were activated in a furnace at 600° C. for 20 min in an ambient environment. The n-GaN and p-GaN layers were grown using trimethylgallium (TMGa), and ammonia (NH₃), silane (SiH₄), and bis (cyclopentadienyl) magnesium (Cp₂Mg) were used as n and p dopant sources. For the InGaN/GaN/AlGaN MQW, layers were grown with triethylgallium (TEGa), trimethylindium (TMI), trimethylaluminum (TMAl), and NH₃. The conventional structure (InGaN/AlGaN) for comparison with the InGaN/GaN/AlGaN active region was not experimentally studied. The growth condition of the active region impacted both crystal quality and device performance significantly. Therefore, it is difficult to make a fair comparison between InGaN/GaN/AlGaN structure and InGaN/AlGaN structure since they will be grown in different MOCVD growth conditions. The growth temperatures used to grow the LED structures were as follows: n-GaN=1210° C.; p-GaN=1150° C.; and MQW=930° C. The carrier gases used to grow the LED structures were as follows: n-GaN=H₂; p-GaN=N₂+H₂; and MQW-InGaN QW=N₂, GaN interlayer=N₂; AlGaN QB=N₂+H₂.

After MOCVD growth, the samples were first patterned by a Heidelberg DWL 66+ laser writer. A 7 nm thick nickel as p-type ohmic contact was deposited by electron beam evaporation. The n-type contact region was exposed by a 300 nm deep dry etch using chlorine (Cl₂) etch chemistry (ICP-RIE) (Plasma-Therm SLR-770I-8R-ICP) at 15 W of RIE power, resulting in 20×20 μm², 40×40 μm², 60×60 μm², and 100×100 μm² μLEDs. A 30 nm thick Atomic Layer Deposited (ALD) Al₂O₃ (Fiji G2 ALD) followed by 250 nm thick Plasma Enhanced Chemical Vapor Deposition (PECVD) SiNₓ (Plasma-Therm 73/72) passivation layers were deposited followed by via opening and pad metal and n-contact (Ti/Ni, 50 nm/250 nm) deposition using e-beam evaporation.

In this Example, electroluminescence (EL) measurements were conducted from the back side of the samples. As LED devices were probed from the top, light transmitted through the substrate was collected from the backside with a cosine corrector (Ocean Insight CC-3-UV-S) and then guided through an optical fiber. In order to match the f-number of the spectrometer, output light from the optical fiber was collimated and refocused by two Plano-Convex lenses before entering the spectrometer (Horiba iHR320)). A thermoelectrically cooled CCD detector (Horiba Synapse CCD) was used with iHR320 spectrometer to obtain EL spectra. This optical system was calibrated by using a radiometric calibrated light source (Ocean Insight DH-3P-CAL).

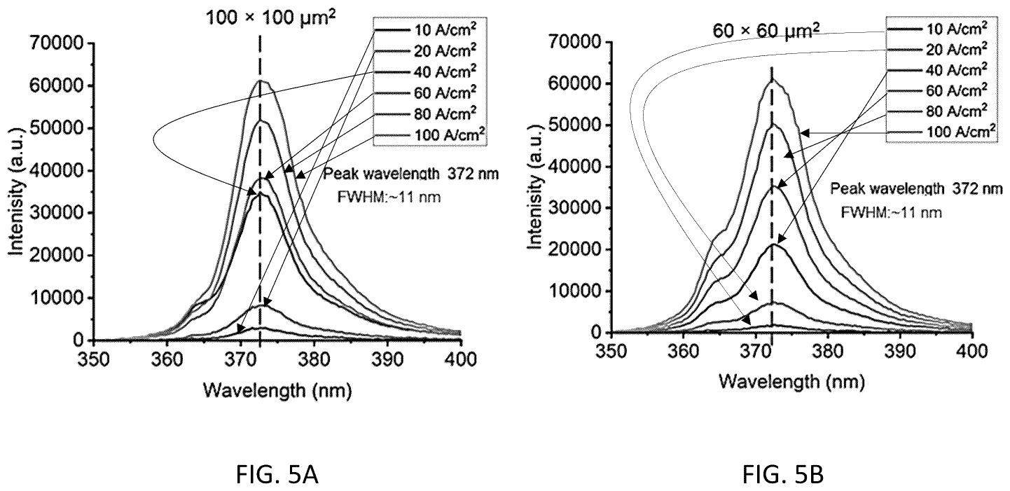

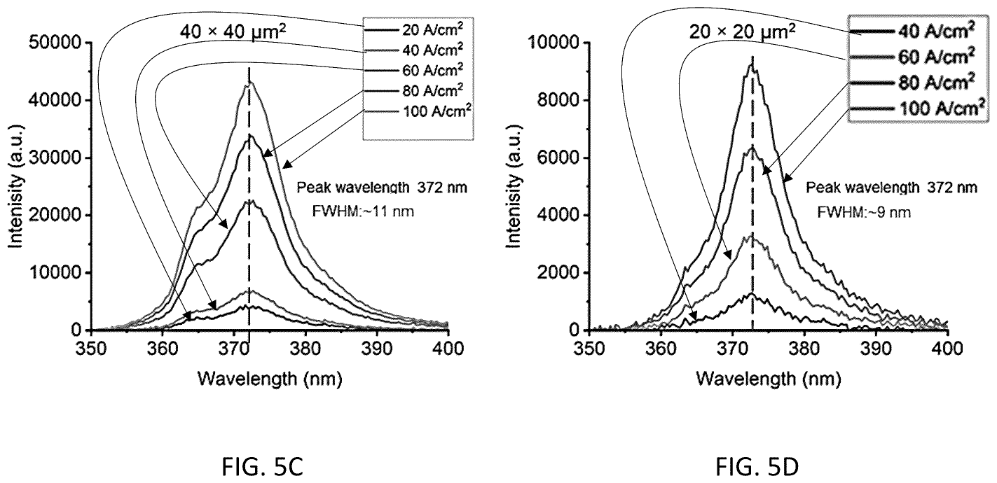

EL spectra of 20×20 μm² to 100×100 μm² devices are shown in FIGS. 5A-5D. The devices were measured with different current densities that ranged from 10 A/cm² to 100 A/cm², and the acquisition time was adjusted according to the intensity. EL intensity increased with increasing current density with a steady peak wavelength of 372 nm. The smaller size devices showed a minor improvement in the full wave half maximum (FWHM). Devices with mesa size 20×20 μm² showed an improved FWHM of 9 nm, while in comparison other larger devices showed a FWHM of 11 nm. The emission spectra are asymmetric, which indicate that there may be absorption and re-emission of the UV light by the n-GaN, the undoped GaN buffer layer, and p-GaN layers. The emission wavelength of the μLEDs is approximately 372 nm, which is in close proximity to the bandgap energy of GaN (3.4 eV/around 365 nm). This may lead to a reduced efficiency in UV-LEDs. One way to solve this issue is to introduce aluminum content into different layers in the structure. The addition of aluminum will tune the bandgap to decrease the absorption of the emitted light, which will improve the overall EQE.

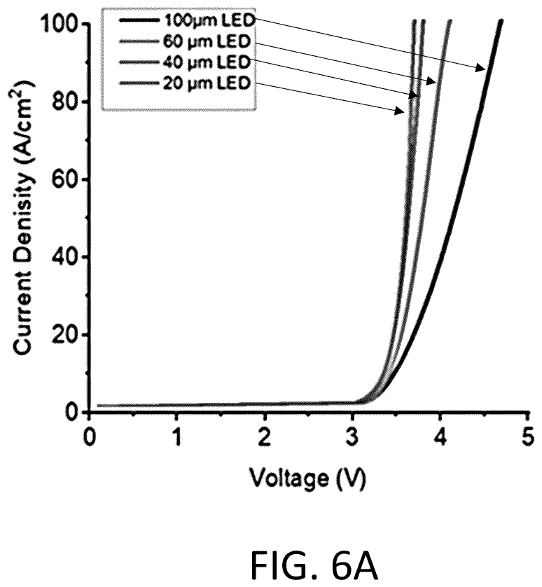

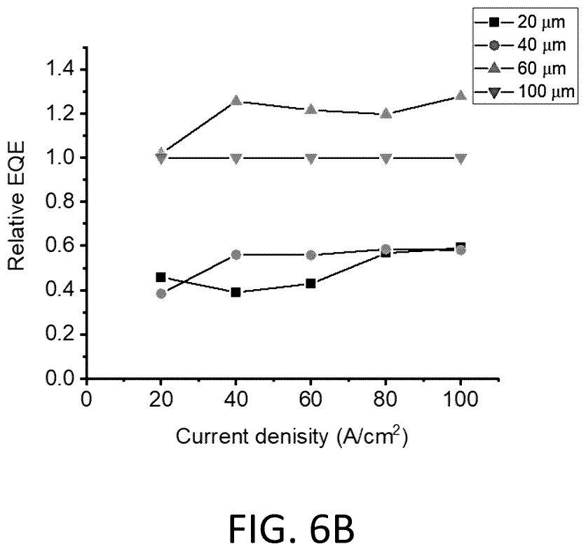

The current density (J) versus the forward voltage (V) of the fabricated μLEDs at room temperature is shown in FIG. 6A. The J-V characteristics showed an inverse relationship of injection current density with device size at the same voltage. When decreased from a device size of 100×100 μm² to a device size of 20×20 μm², the current density increased from 16 A/cm² to 63 A/cm² at 3.5 V. This increase may be attributed to improved heat dissipation as well as reduced current crowding in smaller μLEDs.

In comparison with the 100×100 μm² devices, device sizes of 60× 60 μm² showed a ˜20% increase in the EQE (FIG. 6B). This increase in the EQE of 60×60 μm² device may be attributed to improved light extraction efficiency and reduced current crowding in smaller μLEDs. However, as the device size decreased to 40×40 μm² and 20×20 μm², the devices showed a lower EQE in comparison to the 100×100 μm² device. For current density of 60 A/cm² and below, 40×40 μm² and 20×20 μm² devices showed a relative EQE of 0.6 and 0.4 respectively. It is plausible that the sidewall damage became more prevalent for the smaller sized μLEDs due to the decrease in surface area to volume ratio, which can significantly impact the device performance. As the current density increased, the current crowding effect became more dominant, wherein the smaller sized LEDs started to show advantages in heat dissipation and reduced current crowding effect, which might explain the increase in relative EQE for 20×20 μm² device compared to 40×40 μm² device at higher current density.

In this Example, a novel active region design of InGaN/GaN/AlGaN structure for high-efficiency LED was presented and evaluated through both simulations and experiments. The simulations demonstrated that the InGaN/GaN/AlGaN active region design predicted a 15% improvement at 20 A/cm² and remained at greater than 10% in the operating current density range from 0 to 100 A/cm² when compared to the conventional InGaN/AlGaN structure. With increasing current density, smaller micro-LED devices showed an improvement in relative EQE due to their advantage in current spreading.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A light-emitting device comprising:
an active region comprising one or more quantum wells, wherein the one or more quantum wells are formed by one or more repeating periods of a heterostructure comprising:
a well layer comprising In_{z}Ga_{1-z}N, where 0<z≤0.3, or AlᵢInⱼGa₁₋ᵢ₋ⱼN, where 0<i≤1 and 0<j≤1;
an interlayer comprising GaN; and
a barrier layer comprising Al_{y}Ga_{1-y}N, where 0<y≤1, or AlₖInₗGa₁₋ₖ₋ₗN, where 0<k≤1 and 0<l≤1;
a first electrically conductive contact in electrical communication with a first side of the active region;
a second electrically conductive contact in electrical communication with a second, opposing side of the active region; and
a voltage source connected to the first and second electrically conductive contacts;
wherein the first electrically conductive contact, the second electrically conductive contact, and the voltage source are configured to apply an electric field across the active region.

2. The light-emitting device of claim 1, wherein the well layer has a thickness of no greater than 15 nm, the interlayer has a thickness of no greater than 15 nm, and the barrier layer has a thickness of no greater than 25 nm.

3. The light-emitting device of claim 1, wherein the light-emitting device is a light-emitting diode.

4. The light-emitting device of claim 2, wherein the light-emitting diode further comprises:
an electron-injection layer comprising n-GaN, n-InGaN, n-AlGaN, or n-AlInGaN; and
a hole-injection layer comprising p-GaN, p-InGaN, p-AlGaN, or p-AlInGaN;
wherein the active region is disposed between the electron-injection layer and the hole-injection layer.

5. The light-emitting device of claim 1, wherein the light-emitting device is a laser diode.

6. The light-emitting device of claim 5, wherein the laser diode further comprises:
a first waveguide layer comprising undoped or p-type doped AlGaN, undoped or p-type doped AlInGaN, or undoped or p-type doped GaN;
a second waveguide layer comprising undoped or n-type doped AlGaN, undoped or n-type doped AlInGaN, or undoped or n-type doped GaN, wherein the active region is disposed between the first waveguide layer and the second waveguide layer;
a first cladding layer comprising p-AlGaN over the first waveguide layer; and
a second cladding layer comprising n-AlGaN on the second waveguide layer.

7. The light-emitting device of claim 1, wherein the well layers comprise the In_{z}Ga_{1-z}N.

8. The light-emitting device of claim 1, wherein the well layers comprise the AlᵢInⱼGa₁₋ᵢ₋ⱼN.

9. The light-emitting device of claim 1, wherein the barrier layers comprise the Al_{y}Ga_{1-y}N.

10. The light-emitting device of claim 1, wherein the barrier layers comprise the AlₖInₗGa₁₋ₖ₋ₗN.

11. The light-emitting device of claim 1, wherein the well layers comprise the In_{z}Ga_{1-z}N and the barrier layers comprise the Al_{y}Ga_{1-y}N.

12. The light-emitting device of claim 1, wherein the Al_{y}Ga_{1-y}N or AlₖInₗGa₁₋ₖ₋ₗN of at least one of the one or more quantum wells has an Al content that increases or decreases through a thickness of the barrier layer.

13. The light-emitting device of claim 12, wherein the Al_{y}Ga_{1-y}N or AlₖInₗGa₁₋ₖ₋ₗN of at least one of the one or more quantum wells has a graded composition through a thickness of the barrier layer.

14. The light-emitting device of claim 12, wherein the Al_{y}Ga_{1-y}N or AlₖInₗGa₁₋ₖ₋ₗN of at least one of the one or more quantum wells has a stepped composition comprising two or more strata having different Al_{y}Ga_{1-y}N or AlₖInₗGa₁₋ₖ₋ₗN compositions.

15. The light-emitting device of claim 14, wherein the Al_{y}Ga_{1-y}N or AlₖInₗGa₁₋ₖ₋ₗN in the strata has a graded composition.

16. The light-emitting device of claim 1, wherein at least one of the In_{z}Ga_{1-z}N, AlᵢInⱼGa₁₋ᵢ₋ⱼN, GaN, Al_{y}Ga_{1-y}N, or AlₖInₗGa₁₋ₖ₋ₗN is externally doped with a p-type or n-type dopant.

17. A method of generating light, the method comprising applying an electric field across an active region of a light-emitting device, the active region comprising:
a well layer comprising In_{z}Ga_{1-z}N, where 0<z≤0.3, or AlᵢInⱼGa₁₋ᵢ₋ⱼN, where 0<i≤1 and 0<j≤1;
an interlayer comprising GaN; and
a barrier layer comprising Al_{y}Ga_{1-y}N, where 0<y≤1, or AlₖInₗGa₁₋ₖ₋ₗN, where 0<k≤1 and 0<l≤1,
whereby light is generated in the active region by the recombination of holes and electrons in the active region.

18. A method of growing a periodic group III-nitride heterostructure, the method comprising:
growing a first period of the group III-nitride heterostructure using the steps of:
(a) depositing a well layer comprising In_{z}Ga_{1-z}N, where 0<z≤0.3, or AlᵢInⱼGa₁₋ᵢ₋ⱼN, where 0<i≤1 and 0<j≤1, on a substrate, wherein the well layer is deposited via metal organic chemical vapor deposition from two or more metal organic precursor molecules and one or more nitrogen-containing precursor molecules in a carrier gas composition comprising N₂;
(b) depositing an interlayer comprising GaN on the well layer, wherein the interlayer is deposited via metal organic chemical vapor deposition from two or more metal organic precursor molecules and one or more nitrogen-containing precursor molecules in a carrier gas composition comprising H₂, N₂, or a mixture of H₂ and N₂;
(c) depositing a barrier layer comprising Al_{y}Ga_{1-y}N, where 0<y≤1, or AlₖInₗGa₁₋ₖ₋ₗN, where 0<k≤1 and 0<l≤1, on the interlayer, wherein the barrier layer is deposited via metal organic chemical vapor deposition from two or more metal organic precursor molecules and one or more nitrogen-containing precursor molecules in a carrier gas comprising H₂, N₂, or a mixture of H₂ and N₂;
(d) varying the carrier gas composition, a growth temperature, or both during the deposition of the well layer, the interlayer, or both; and
repeating steps (a)-(d) one or more times to grow one or more additional periods of the group III-nitride heterostructure, wherein the substrate in step (a) for each of the one or more additional layers is the barrier layer of a previous period of the group III-nitride heterostructure.

19. The method of claim 18, wherein the well layer has a thickness of no greater than 15 nm, the interlayer has a thickness of no greater than 15 nm, and the barrier layer has a thickness of no greater than 25 nm.

20. The method of claim 18, wherein both the carrier gas composition and the growth temperature are varied in step (b), in step (c), or in both steps (b) and (c).

21. The method of claim 18, wherein the carrier gas composition in step (b) initially consists of N₂ and is varied during the deposition of the interlayer by introducing H₂ into the carrier gas composition.

22. The method of claim 18, wherein the carrier gas composition in step (c) comprises the mixture of H₂ and N₂ and a ratio of H₂ to N₂ in the mixture is varied during the deposition of the barrier layer.

23. The method of claim 18, wherein the growth temperature is increased during the growth of the interlayer in step (b), during the growth of the barrier layer in step (c), or both.

24. The method of claim 18, wherein relative concentrations of the metal organic precursor molecules and the nitrogen-containing precursor molecules are varied during step (c), such that the barrier layer has a graded or stepped composition profile.
